(19) United States
(12) Patent Application Publication
(10) Pub. No.: US 2025/0313943 A1
(43) Pub. Date: Oct. 9, 2025

(54) Sputtering Target, Method for Manufacturing Laminated Film, Laminated Film, and Magnetic Recording Medium

(71) Applicant: JX Advanced Metals Corporation, Tokyo (JP)

(72) Inventors: Masayoshi Shimizu, Ibaraki (JP); Manami Masuda, Ibaraki (JP); Yasuyuki Iwabuchi, Ibaraki (JP); Kazuya Honda, Ibaraki (JP)

(21) Appl. No.: 18/856,321

(22) PCT Filed: May 26, 2023
(86) PCT No.: PCT/JP2023/019793

§ 371 Date: Jun. 10, 2025

(30) Foreign Application Priority Data
Sep. 6, 2022 (JP) 2022141684

(51) Int. Cl. C23C 14/34; G11B 5/851; G11B 5/852

(52) U.S. Cl. CPC C23C 14/3414; G11B 5/851; G11B 5/852

(57) ABSTRACT

A sputtering target capable of maintaining high coercive force in the magnetic layer of a magnetic recording medium and improving magnetic separation between magnetic particles is provided. A sputtering target includes Co and Pt as metal components and NbO₂ as a metal oxide component. Or alternatively, a sputtering target includes Co and Pt as metal components, and includes a phase containing Co, Nb, and O.

### FIELD OF THE INVENTION

The present invention relates to a sputtering target. The present invention also relates to a method for manufacturing a laminated film using the sputtering target of the present invention. Furthermore, the present invention also relates to a laminated film and a magnetic recording medium.

### BACKGROUND OF THE INVENTION

In hard disk drives, the perpendicular magnetic recording method, which records magnetic fields perpendicular to the recording surface, has been put into practical use. This method is widely adopted because it allows for higher density recording than the previous in-plane magnetic recording method.

A magnetic recording medium for perpendicular magnetic recording is generally constructed by sequentially laminating an adhesion layer, a soft magnetic layer, a seed layer, an underlayer such as a Ru layer, an intermediate layer, a magnetic layer, and a protective layer on a substrate such as aluminum or glass. Among these, the magnetic layer has a granular film in the lower part, in which SiO₂ and other metal oxides are dispersed in a Co—Pt alloy or the like containing Co as the main component, and has high saturation magnetization Ms and magnetic anisotropy Ku. In addition, the intermediate layer laminated below the magnetic layer has a structure in which similar metal oxides are dispersed in a Co—Cr —Ru alloy or the like, and may contain relatively large amounts of Ru, Cr, or the like to make it non-magnetic.

In such magnetic layers and intermediate layers, the above-mentioned metal oxides, which serve as non-magnetic materials, precipitate at the grain boundaries of magnetic particles such as Co alloys that are oriented in the perpendicular direction, thereby reducing the magnetic interaction between the magnetic particles, thereby improving noise characteristics and achieving high recording density.

In addition, generally, each layer, such as the magnetic layer and intermediate layer, is formed by sputtering a sputtering target having a predetermined composition or structure onto a substrate. Conventional techniques of this type include the one described in Patent Literature 1 (Japanese Patent No. 5960287).

### PRIOR ART

### Patent Literature

[Patent Literature 1] Japanese Patent No. 5960287

### SUMMARY OF THE INVENTION

On the other hand, in order to achieve high density hard disk drives, it is necessary to increase the magnetic anisotropy Ku to ensure the thermal stability of the recording layer formed on the magnetic recording medium, and to have high magnetic separation of the magnetic particles in the recording layer to achieve high resolution.

However, in a magnetic layer having a high saturation magnetization Ms that realizes a high magnetic anisotropy Ku as described above, the exchange coupling between magnetic grains is strong, and therefore the magnetic separation between magnetic grains is poor. On the other hand, if a large amount of metal oxide is added to improve magnetic separation, the metal oxide penetrates into the magnetic particles, deteriorating the crystallinity of the magnetic particles, thereby decreasing the saturation magnetization Ms and magnetic anisotropy Ku, and decreasing the coercive force Hc. In addition, there is also a method of increasing the substrate temperature during film formation in order to increase the magnetic anisotropy Ku, but this also reduces the magnetic separation between magnetic particles, thereby decreasing the coercive force Hc. To achieve high density, it is important that the recording layer has both a high coercive force Hc and magnetic separation between magnetic grains in the recording layer.

The present invention was completed in consideration of the above problems, and in one embodiment, an object of the present invention is to provide a sputtering target that is capable of maintaining a high coercive force Hc in the magnetic layer of a magnetic recording medium while improving the magnetic separation between magnetic particles. In another embodiment, an object of the present invention is to provide a method for manufacturing a laminated film using such a sputtering target, a laminated film, and a magnetic recording medium.

As a result of extensive research, the inventors have discovered that by including Nb as an oxide in a specific form as a metal oxide of a non-magnetic material dispersed in a Co alloy, which is the magnetic material of the magnetic layer, the magnetic separation between magnetic particles can be significantly improved. It was also found that this makes it possible to maintain a high coercive force Hc of the magnetic layer mainly composed of Co—Pt. The present invention has been completed based on the above findings, and is exemplified as below.
[1] A sputtering target, comprising Co and Pt as metal components and NbO₂ as a metal oxide component.
[2] The sputtering target according to [1], wherein a content of NbO₂ is 0.5 mol % to 30 mol %.
[3] A sputtering target, comprising Co and Pt as metal components, and a phase comprising Co, Nb, and O.
[4] The sputtering target according to [3], wherein a diffraction peak is observed at 2θ=30.27°±1° when measured using an X-ray diffraction device.
[5] The sputtering target according to [4], wherein a diffraction peak is observed at 2θ-30.27°±1° when measured under the following conditions:
(1) An analysis area of the sputtering target is a cut surface perpendicular to the sputtered surface.
(2) Cu-Kα is used as an X-ray source.
(3) A tube voltage is 40 kV.
(4) A tube current is 30 mA.
(5) A divergence slit is 1°.
(6) A divergence vertical limiting slit is 10 mm.
(7) A scattering slit is 8 mm.
(8) A receiving slit is in the open state.
(9) A horizontal-sample goniometer is used.
(10) A scan speed is 10°/min.
(11) A scan step is 0.01°.
(12) A measurement range is 20=20° to 80°.
(13) A fitting method is used for background removal.
(14) An analysis area is polished with #2000 waterproof abrasive paper and then buffed with a slurry containing dispersed alumina abrasive grains with a particle size of 0.3 μm.
(15) Of the analysis area, a flat surface with minimal irregularities is measured.
[6] The sputtering target according to any one of [1] to [5], further comprising at least one metal oxide selected from the group consisting of TiO₂, SiO₂, Cr₂O₃, B₂O₃, CoO and Co₃O₄ as a metal oxide component, and a total content of the metal oxides in the sputtering target is 20 vol % to 60 vol %.
[7] The sputtering target according to any one of [1] to [6], wherein a content of Pt is 2 mol % to 25 mol %.
[8] A method for manufacturing a laminated film, comprising forming a magnetic layer on an underlayer comprising Ru by performing sputtering using the sputtering target according to any one of [1] to [7].
[9] A laminated film, comprising an underlayer comprising Ru, and a magnetic layer formed on the underlayer and comprising Co and Pt as metal components, wherein the magnetic layer comprises NbO₂ as a metal oxide component.
[10] The laminated film according to [9], wherein the magnetic layer further comprises at least one metal oxide selected from the group consisting of TiO₂, SiO₂, Cr₂O₃, B₂O₃, CoO and Co₃O₄ as a metal oxide component.
[11] A magnetic recording medium comprising the laminated film according to [9] or [10].

According to one embodiment of the present invention, it is possible to provide a sputtering target that is capable of maintaining a high coercive force in the magnetic layer of a magnetic recording medium while improving the magnetic separation between magnetic particles. Further, according to another embodiment of the present invention, it is possible to provide a method for manufacturing a laminated film using such a sputtering target, a laminated film, and a magnetic recording medium.

### BRIEF DESCRIPTION OF THE DRAWINGS

FIG. 1 is a schematic diagram showing the layer structure of a laminated film produced in an example of the present invention.

FIG. 2 shows the results of measurement using XRD of a target in an example of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention.

The sputtering target of the present embodiment is characterized by containing Co and Pt as metal components and NbO₂ as a metal oxide component. More specifically, the sputtering target of the present embodiment has a structure in which metal oxides including Nb oxide are dispersed in an alloy of Co and Pt. In addition, when metal oxide components are mentioned in this specification, unless otherwise specified, the description refers to the metal oxide as a raw material of the sputtering target.

This sputtering target is particularly suitable for use in forming a magnetic layer located on an intermediate layer of a magnetic recording medium of the perpendicular magnetic recording system. In this case, in the magnetic layer formed by sputtering using the sputtering target, The above metal components constitute the magnetic particles, while the metal oxides including NbO₂ act as non-magnetic materials that are uniformly distributed around the magnetic particles oriented in the perpendicular direction, effectively reducing the magnetic interactions between the magnetic particles.

### (1. Composition)

The metal component of the sputtering target is mainly composed of Co and additionally contains Pt. In particular, the metal component is a Co alloy containing Pt.

The content of Pt is preferably 2 mol % to 25 mol %. If the total Pt content is too high, the magnetic anisotropy may decrease and the crystallinity of the magnetic particles may decrease. On the other hand, if the ratio of the total Pt content to the Co content is too small, there is a concern that the magnetic anisotropy may be insufficient. In addition, the content of Pt in the sputtering target can be determined, for example, by analyzing the target using ICP and based on the analysis results.

The sputtering target of the present embodiment may further contain Cr, Ru, Ti, Cu, Ta, W, V, Rh, or the like as a non-magnetic metal component. By further containing such a metal, there is an advantage that the saturation magnetization and magnetic anisotropy can be adjusted while maintaining the crystallinity of the magnetic particles. In addition, although many of these metals are usually contained as metal components, some of them may be contained as metal oxides due to being oxidized during sintering during manufacture, which will be described later.

The sputtering target of the present embodiment contains at least NbO₂ as a metal oxide component. By containing NbO₂, it is possible to improve the magnetic separation between magnetic particles while maintaining the coercive force.

Although there is no intention to restrict the present invention to any theory, Nb oxide has an appropriate wettability with Co and can remain a stable oxide even if some oxygen is lost, which has the advantage that grain boundaries of uniform width can be formed around the magnetic particles without the oxide penetrating into the magnetic particles. The present inventors have also observed that the advantage becomes more pronounced when Nb oxide with a smaller oxidation number is used. This is believed to be because the formation of a composite oxide with Co improves wettability with Co. Therefore, by including NbO₂, which has a low oxidation number among Nb oxides, it has been possible to realize magnetic separation between magnetic particles that could not be achieved with conventional technology.

In the sputtering target of the present embodiment, the content of NbO₂ is preferably 0.5 mol % to 30 mol % with respect to the total composition of the raw materials of the sputtering target. By setting the NbO₂ content to 0.5 mol % or more, the effect of enhancing the magnetic separation between magnetic particles can be ensured. On the other hand, the content of NbO₂ is preferably 30 mol % or less from the viewpoint of preventing the effect from reaching a plateau and ensuring the saturation magnetization and magnetic anisotropy of the magnetic film to obtain a high coercive force. From this viewpoint, the content of NbO₂ is more preferably 20 mol % or less, and even more preferably 10 mol % or less.

Furthermore, the sputtering target of the present embodiment may further contain, as a metal oxide component, at least one of TiO₂, SiO₂, Cr₂O₃, and B₂O₃, in addition to NbO₂. This makes it possible to obtain the effect of the metal oxide TiO₂, SiO₂, Cr₂O₃ or B₂O₃ in addition to the effect of NbO₂ described above. In addition, the metal oxide component may contain CoO and Co₃O₄. By adding these Co oxides, the effect of NbO₂ can be enhanced.

When the sputtering target contains metal oxides other than NbO₂ as described above, the total content of the metal oxides present in the sputtering target, that is, the metal oxides constituting the structural structure of the sputtering target, is preferably 20 vol % to 60 vol %. If the total content of the metal oxides is 20 vol % or more, the magnetic separation between the magnetic particles can be sufficiently ensured. On the other hand, if the total content of the metal oxides is 60 vol % or less, the decrease in the coercive force can be prevented. For this reason, it is more preferable that the total content of metal oxides is 30 vol % to 55 vol %. In addition, for example, an image of the surface of the sputtering target can be obtained by SEM and EDS analysis can be performed to classify the particles in the image into metal particles and metal oxide particles, and the volume ratio of metal oxide present in the sputtering target can be estimated based on the area ratio of the metal particles to the metal oxide particles. Further, the metal oxide content can be estimated not only by observing the surface of the sputtering target, but also based on the density, weight, and the like of the raw material powder. The calculation method based on the raw material powder will be described later.

### (2. Method for Manufacturing Sputtering Target)

The above-mentioned sputtering target can be manufactured by using a powder sintering method, and a specific example thereof is as follows.

First, as metal powders, Co powder, Pt powder, and, if necessary, powders of other metals as described above are prepared. The metal powder may be not only a single element but also an alloy powder, and it is preferable that the particle size is within the range of 1 μm to 10 μm, since this allows for uniform mixing and prevents segregation and coarse crystallization. If the particle size of the metal powder is larger than 10 μm, the oxide particles described below may not be uniformly dispersed, and if it is smaller than 1 μm, the oxidation of the metal powder may cause the sputtering target to deviate from the desired composition.

Further, as oxide powders, at least NbO₂ powder is prepared, and if necessary, at least one powder selected from the group consisting of TiO₂, SiO₂, Cr₂O₃ and B₂O₃ are prepared. The oxide powder preferably has a particle size in the range of 1 μm to 30 μm, so that when it is mixed with the metal powder and pressure sintered, the oxide particles can be more uniformly dispersed in the metal phase. If the particle size of the oxide powder is larger than 30 μm, coarse oxide particles may be generated after pressure sintering, whereas if the particle size is smaller than 1 μm, aggregation of the oxide powder particles may occur.

Next, the metal powder and oxide powder are weighed out to obtain a desired composition. For example, NbO₂ powder is weighed out to obtain 0.5 mol % to 30 mol % of the total composition of the raw materials of the sputtering target. In addition, the NbO₂ powder is preferably weighed out to be 0.5 mol % to 20 mol %, and more preferably weighed out to be 0.5 mol % to 10 mol %. In addition, when weighing, for example, the Pt powder is weighed so as to be 2 mol % to 25 mol % with respect to the total composition of the raw materials. Furthermore, when weighing, the oxide powders used as raw materials are weighed so that the total content of metal oxides in the sputtering target is 20 vol % to 60 vol %. Then, the weighed metal powder and oxide powder are then mixed and pulverized using a known technique such as a ball mill. At this time, it is desirable to fill the inside of the container used for mixing and pulverizing with an inert gas to suppress oxidation of the raw material powder as much as possible, thereby obtaining a mixed powder in which the desired metal powder and oxide powder are uniformly mixed.

Thereafter, the mixed powder thus obtained is sintered under pressure in a vacuum atmosphere or an inert gas atmosphere, and molded into a predetermined shape such as a disk. Here, various pressure sintering methods can be used, such as hot press sintering, hot isostatic sintering, plasma discharge sintering, and the like. Among them, the hot press sintering method is effective from the viewpoint of increasing the density of the sintered body.

The holding temperature during sintering is preferably in the range of 700° C. to 1500° C., and more preferably in the range of 800° C. to 1400° C. In addition, the time for which the temperature is held within this range is preferably 1 hour or more. In addition, the pressure during sintering is preferably 10 MPa to 40 MPa, and more preferably 25 MPa to 35 MPa. In this manner, it is possible to prepare a sintered body in which oxide particles are more uniformly dispersed in the metal phase while maintaining a high density.

The sintered body obtained by the above pressure sintering can be cut into a desired shape using a lathe or other mechanical processing, thereby manufacturing a sputtering target.

### (3. Composition Structure of the Sputtering Target)

The sputtering target of the present embodiment contains NbO₂ as a metal oxide component of the raw material, and corresponding to this feature, one of the features of the sputtering target is that it has a phase containing Co, Nb, and O.

Although there is no intention to restrict the present invention to any theory, it is presumed that magnetic grains in a thin film made using a target containing a phase containing each of Co, Nb, and O can form oxide grain boundaries of uniform width around them, thereby improving the magnetic separation between the magnetic grains. Such phases are typical of sputtering targets containing NbO₂ as the metal oxide component.

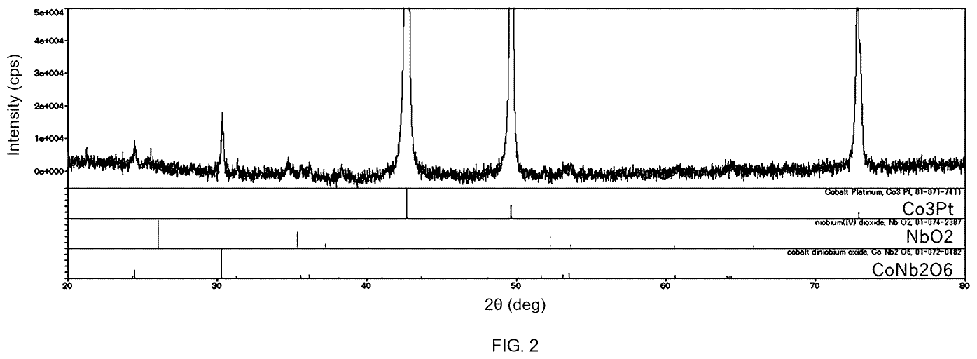

The phase containing all of Co, Nb, and O can be confirmed by, for example, X-ray diffraction (XRD). That is, in an XRD pattern using Cu-Kα, it has a diffraction peak at approximately 2θ=30.27°±1°. In the explanation of FIG. 2, which will be described later, it is stated that this diffraction peak corresponds to the peak of CoNb₂O₆, but it is considered that this may be, for example, CoNb₂O₆₋₈ (δ>0), that is, there may be a possibility that the oxygen content is somewhat low. Including these cases, it can be determined that the phase contains each of Co, Nb, and O. This phase is considered to have been formed by the reaction of Co and NbO₂.

Thus, in the present embodiment, the presence or absence of a phase containing each of Co, Nb, and O is used as a means for verifying that the raw material contains NbO₂ as a metal oxide component.

In addition, when a phase containing each of Co, Nb, and O is present, it can be inferred that the raw material contains NbO₂ as a metal oxide. However, for example, if the raw material NbO₂ does not react significantly with other metal components and/or oxides during the manufacturing process, it is theoretically possible that a phase containing each of Co, Nb, and O may not be detected. Furthermore, when the sputtering target contains NbO₂ as a metal oxide component, a diffraction peak corresponding to NbO₂ may be detected by XRD. In at least such a case, it can be said that NbO₂ is present in the sputtering target and constitutes its texture. However, during the process of sintering the raw material powders, almost all of the NbO₂ may react with other metal components and/or oxides to form other compounds, so that a diffraction peak corresponding to NbO₂ may not be detected from the sputtering target.

### (4. Laminated Film)

A laminated film has at least an underlayer and a magnetic layer formed on the underlayer. More specifically, the underlayer contains Ru, and is generally made of Ru or is a layer mainly composed of Ru.

The magnetic layer contains Co and Pt as metal components, and Nb oxide as a metal oxide component. The magnetic layer contains Nb oxide, which improves the magnetic separation between magnetic particles. This magnetic layer can be formed by sputtering a sputtering target having the above-mentioned NbO₂ phase or/and a phase containing all of Co, Nb, and O onto the underlayer.

Therefore, similar to the sputtering target described above, for the magnetic layer, it is preferable that the content of NbO₂ be 0.5 mol % to 30 mol %; when the metal oxide component further contains at least one metal oxide selected from the group consisting of TiO₂, SiO₂, Cr₂O₃, B₂O₃, CoO and Co₃O₄, it is preferable that the total content of the metal oxides including NbO₂ be 20 vol % to 60 vol %; it is preferable that the content of Pt be 2 mol % to 25 mol; and it is preferable that the metal component further contain 0.5 mol % to 20 mol % of Cr and/or Ru, respectively.

Each layer of the laminated film can be formed by depositing the layer in a magnetron sputtering device or the like using a sputtering target having a composition and structure appropriate for each layer.

Further, the magnetic layer of the laminated film can be formed on the underlayer by sputtering using the above-mentioned sputtering target.

### (5. Magnetic Recording Medium)

The magnetic recording medium includes a laminated film having an underlayer and a magnetic layer formed on the underlayer, as described above. A magnetic recording medium is usually manufactured by successively forming a soft magnetic layer, an underlayer, a magnetic layer, a protective layer, and the like on a substrate such as aluminum or glass.

### Examples

Next, sputtering targets according to the present invention was prepared and the effects of a magnetic layer formed using the target were confirmed, which will be described below. However, the description here is merely for illustrative purposes and is not intended to be limiting.

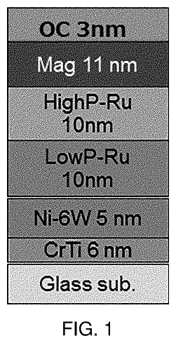

Laminated films were prepared using various sputtering targets. Cr—Ti (6 nm), Ni-6W (5 nm), and Ru (“LowP-Ru” means Ru sputtered at low gas pressure (1 Pa), and “HighP-Ru” means Ru sputtered at high gas pressure (10 Pa). Both had a film thickness of 10 nm, and the total film thickness was 20 nm.) were deposited in this order on a glass substrate using a magnetron sputtering device (Canon Anelva C-3010). To this, a sputtering target shown in Table 1 was sputtered at 300 W in an Ar atmosphere of 3.0 Pa to form a magnetic film with a thickness of 11 nm, and then a Ru (3 nm) film was formed as a protective film (OC) to prevent oxidation, thereby forming each layer. Here, the magnetic layer shown as “Mag” in FIG. 1 was formed using each sputtering target having a different composition as shown in Table 1. The metal fraction composition of each sputtering target was the same, and the metal component was a CoPt alloy containing 27 at % Pt. As the metal oxide component, Examples 1 to 3 contained NbO₂, but Comparative Examples 1 and 2 did not contain NbO₂. In addition, the volume ratio of the oxide was calculated by estimating the volume of the entire sputtering target and the volume of the oxide from the density and weight of the raw material powder, and then calculating the ratio between them. In this way, the volume ratio of the oxide could also be calculated based on the raw material powder.

The coercive force Hc and the magnetic cluster size Dn, which is an index of high magnetic separation of magnetic particles, were measured for the laminated film of each of the Examples and Comparative Examples. The respective measurement methods are as follows.

An external magnetic field (H) was applied perpendicular to the prepared film using a polar Kerr device (BH-810 MS) manufactured by NeoArc Inc. to measure the Kerr rotation angle (θ) and create a hysteresis curve. The maximum applied magnetic field was ±20 kOe, and the magnetic field sweep rate was 0.5 kOe/sec. The obtained hysteresis curve (major hysteresis curve) was analyzed to determine the coercive force Hc.

Next, after the applied magnetic field was temporarily set to 20 kOe, the magnetic field was swept down to —Hc and then swept up to 20 kOe again to obtain a minor hysteresis curve. Next, dθ/dH was calculated by differentiating the major and minor loops. The horizontal axis was replaced with the effective magnetic field (Heff) calculated using the formula:

$$Effective magnetic field ( Heff ) = H - demagnetizing field Hd$$

The value of this demagnetizing field, Hd, was determined so that when dθ/dH obtained from the major loop and dθ/dH obtained from the minor loop are plotted with the horizontal axis representing the effective magnetic field, the graphs overlap where dθ/dH increases.

Next, the saturation magnetization Ms was measured using a vibrating sample magnetometer (VSM) manufactured by Tamagawa Seisakusho.

The demagnetizing field coefficient Nd was calculated using the following formula:

$$Demagnetizing factor Nd = Hd / ( 4 π Ms )$$

The magnetic cluster size Dn was calculated using the calculated Nd and the thickness t of the magnetic film of the sample using the following formula:

$$Magnetic cluster size Dn = t \times {( 1 - {Nd}^{2} )}^{1 / 2} / Nd$$

TABLE 1

| | Metal | Oxide | Oxide total | NbO₂ oxide | NbO₂ | Coercive | Magnetic cluster |
|---|---|---|---|---|---|---|---|
| | fraction | species | volume ratio | volume ratio | oxide ratio | force | size Dn |
| | Composition | contained | (vol %) | (vol %) | (mol %) | (kOe) | (nm) |
| Example 1 | Co—27Pt | B₂O₃, TiO₂, SiO₂, CoO, Cr₂O₃, NbO₂ | 42 | 5.8 | 2.9 | 9.2 | 12.2 |
| Example 2 | Co—27Pt | B₂O₃, TiO₂, SiO₂, CoO, Cr₂O₃, NbO₂ | 42 | 5.4 | 2.6 | 9.0 | 10.9 |
| Example 3 | Co—27Pt | B₂O₃, TiO₂, SiO₂, CoO, Cr₂O₃, NbO₂ | 37.5 | 5.3 | 2.5 | 8.7 | 11.5 |
| Comparative | Co—27Pt | B₂O₃, TiO₂, SiO₂, CoO, Cr₂O₃ | 42 | 0 | 0 | 8.6 | 14.7 |
| Example 4 | | | | | | | |
| Comparative | Co—27Pt | B₂O₃, TiO₂, SiO₂, CoO, Cr₂O₃ | 37.5 | 0 | 0 | 8.3 | 13.2 |
| Example 5 | | | | | | | |

As shown in Table 1, in Examples 1 to 3, which contained NbO₂, a relatively high coercive force Hc and a relatively low magnetic cluster size Dn were obtained, and the coercive force was maintained high while improving the magnetic separation between magnetic particles. In contrast, in Comparative Examples 1 and 2 which did not contain NbO₂, although the other components were almost the same, the coercive force Hc and the magnetic cluster size Dn were inferior.

FIG. 2 shows the results of XRD measurement of the target in Example 3. The XRD analysis conditions are as follows.

When analyzing a sputtering target using an X-ray diffraction device (Rigaku Ultima IV), the measurement method can be performed in accordance with JIS K0131: 1996, and the measurement conditions can be as follows.

Analysis area of sputtering target: Cut surface perpendicular to the sputter surface
X-ray source: Cu-Kα
Tube voltage: 40 kV
Tube current: 30 mA
Divergence slit: 1°
Divergence vertical limit slit: 10 mm
Scattering slit: 8 mm
Receiving slit: Open state
Goniometer: Horizontal-sample type
Scan speed: 10°/min
Scan step: 0.01°
Measurement range: 2θ=20° to 80°

Background removal: Fitting method (more specifically, a simple peak search is performed, the peak portion is removed, and then a polynomial is fitted to the remaining data. Background removal is performed based on X-ray analysis software (Rigaku Holdings Corporation, Integrated Powder X-ray Analysis Software PDXL2).)

In addition, the analysis area is polished with #2000 waterproof abrasive paper, and then buffed with a slurry containing dispersed alumina abrasive grains with a particle size of 0.3 μm, and the flat surface with the least irregularities is measured. It should be noted that “a flat surface with minimal irregularities” is not a strict standard, but merely means that if there are irregularities that may interfere with the analysis, those areas should be avoided.

The obtained XRD pattern was analyzed using X-ray analysis software (Rigaku Holdings Corporation, integrated powder X-ray analysis software PDXL2). As a result, as can be seen from FIG. 2, a diffraction peak was observed near 2θ=30.27°±1°. By comparing the position of the observed diffraction peak with the data on the position of the diffraction peak of CoNb₂O₆ in JCPDS card No. 01-072-0482, it was confirmed that the position of the observed peak corresponds to the position of the main peak (2θ=) 30.27° in JCPDS card No. 01-072-0482. That is, it was confirmed that the alloy had a phase containing each of Co, Nb, and O. In addition, no diffraction peak corresponding to NbO₂ was observed in FIG. 2, but this is considered to be because, as described above, almost all of the NbO₂ in the raw material reacted with metal components and/or oxides during the sintering process.

1. A sputtering target, comprising Co and Pt as metal components and NbO₂ as a metal oxide component.

2. The sputtering target according to claim 1, wherein a content of NbO₂ is 0.5 mol % to 30 mol %.

3. A sputtering target, comprising Co and Pt as metal components, and a phase comprising Co, Nb, and O.

4. The sputtering target according to claim 3, wherein a diffraction peak is observed at 2θ=30.27°±1° when measured using an X-ray diffraction device.

5. The sputtering target according to claim 4, wherein a diffraction peak is observed at 2θ-30.27°±1° when measured under the following conditions:
(1) An analysis area of the sputtering target is a cut surface perpendicular to the sputtered surface.
(2) Cu-Kα is used as an X-ray source.
(3) A tube voltage is 40 kV.
(4) A tube current is 30 mA.
(5) A divergence slit is 1°.
(6) A divergence vertical limiting slit is 10 mm.
(7) A scattering slit is 8 mm.
(8) A receiving slit is in the open state.
(9) A horizontal-sample goniometer is used.
(10) A scan speed is 10°/min.
(11) A scan step is 0.01°.
(12) A measurement range is 20=20° to 80°.
(13) A fitting method is used for background removal.
(14) An analysis area is polished with #2000 waterproof abrasive paper and then buffed with a slurry containing dispersed alumina abrasive grains with a particle size of 0.3 μm.
(15) Of the analysis area, a flat surface with minimal irregularities is measured.

6. The sputtering target according to claim 1, further comprising at least one metal oxide selected from the group consisting of TiO₂, SiO₂, Cr₂O₃, B₂O₃, CoO, and Co₃O₄ as a metal oxide component, and a total content of the metal oxides in the sputtering target is 20 vol % to 60 vol %.

7. The sputtering target according to claim 1, wherein a content of Pt is 2 mol % to 25 mol %.

8. A method for manufacturing a laminated film, comprising forming a magnetic layer on an underlayer comprising Ru by performing sputtering using the sputtering target according to claim 1.

9. A laminated film, comprising an underlayer comprising Ru, and a magnetic layer formed on the underlayer and comprising Co and Pt as metal components, wherein the magnetic layer comprises NbO₂ as a metal oxide component.

10. The laminated film according to claim 9, wherein the magnetic layer further comprises at least one metal oxide selected from the group consisting of TiO₂, SiO₂, Cr₂O₃, B₂O₃, CoO, and Co₃O₄ as a metal oxide component.

11. A magnetic recording medium comprising the laminated film according to claim 9.

12. The sputtering target according to claim 3, further comprising at least one metal oxide selected from the group consisting of TiO₂, SiO₂, Cr₂O₃, B₂O₃, CoO, and Co₃O₄ as a metal oxide component, and a total content of the metal oxides in the sputtering target is 20 vol % to 60 vol %.

13. The sputtering target according to claim 3, wherein a content of Pt is 2 mol % to 25 mol %.

14. A method for manufacturing a laminated film, comprising forming a magnetic layer on an underlayer comprising Ru by performing sputtering using the sputtering target according to claim 3.
